(19) United States
(12) Patent Application Publication
(10) Pub. No.: US 2018/0222152 A1
(43) Pub. Date: Aug. 9, 2018

(54) RESIN-CLAD COPPER FOIL, AND PRINTED WIRING BOARD

(71) Applicant: TATSUTA ELECTRIC WIRE & CABLE CO., LTD., Higashiosaka-shi, Osaka (JP)

(72) Inventors: Hiroaki Umeda, Kizugawa-shi (JP); Masanori Miyamoto, Kizugawa-shi (JP); Kazuhiro Matsuda, Kizugawa-shi (JP); Ken Yukawa, Kizugawa-shi (JP); Shirou Yamauchi, Kizugawa-shi (JP)

(73) Assignees: TATSUTA ELECTRIC WIRE & CABLE CO., LTD., Higashiosaka-shi, Osaka (JP); TATSUTA ELECTRIC WIRE & CABLE CO., LTD., Higashiosaka-shi, Osaka (JP)

(21) Appl. No.: 15/742,994

(22) PCT Filed: Jul. 14, 2016
(86) PCT No.: PCT/JP2016/003333

§ 371 Date: Jan. 9, 2018

(30) Foreign Application Priority Data
Jul. 24, 2015 (JP) 2015-146955

(51) Int. Cl. B32B 15/08; B32B 15/20; C08L 79/08; C08K 3/36; C08L 27/12; H05K 3/02

(52) U.S. Cl. CPC B32B 15/08; B32B 15/20; H05K 3/022; C08K 3/36; C08L 27/12; C08L 79/08

(57) ABSTRACT

Resin-clad copper foil improves transmission characteristics by using a bismaleimide resin having a low dielectric constant and a low dielectric loss tangent. The foil can be manufactured without irradiation with ultraviolet rays. A resin composition is laminated on copper foil. The resin composition includes a bismaleimide resin represented by general formula (I), a curing agent, and a filler, the blending amount of the filler is 10 to 200 parts by mass based on 100 parts by mass of a resin component. The resin composition has a complex viscosity at 80° C. of 1×10³ Pa·s to 5×10⁵ Pa·s. In general formula (I), X represents an aliphatic, alicyclic or aromatic hydrocarbon group having 10 to 30 carbon atoms in the main chain, Y represents an aliphatic, alicyclic, or aromatic hydrocarbon group, and a represents a number in a range of 1 to 20.

### TECHNICAL FIELD

The present invention relates to resin-clad copper foil used mainly for manufacturing a printed wiring board and a printed wiring board using the same.

### BACKGROUND ART

With a spread of information terminals such as a smart phone, a processor and a communication module capable of high-speed processing have appeared, and a transmission speed of electric signals flowing through a circuit board on which the processor and the communication module are mounted has been increased. Therefore, there is an increasing demand for a board material such as a multilayer board with improved transmission characteristics.

The multilayer board can be manufactured as follows. On a surface of a core board, resin-clad copper foil which is obtained by coating copper foil with a B-stage thermosetting resin is overlaid and cured by pressing while heating to form a multilayered layer. Next, a via hole is formed by laser processing, plating is performed to connect the layers, and thereafter the copper foil is etched to form a circuit.

In order to improve the transmission characteristics of the board, there is a demand for using a resin with a low dielectric constant and a low dielectric loss tangent for the resin-clad copper foil used for the board, and for example, fluororesin, liquid crystal polymer, and the like are in practical use. However, the fluororesin is inferior in adhesion, flexibility, and workability, and the liquid crystal polymer is inferior in adhesion and workability. Therefore, a use of a bismaleimide resin has been proposed as a solution to these problems. However, there is a problem that a melt viscosity is low and a flow of the resin occurs at the time of press molding when using the bismaleimide resin. Therefore, there is disclosed a technique of performing temporary curing by performing irradiation with ultraviolet ray before pressing to make a resin into a B stage shape as disclosed in PTL 1. However, there is a problem that unevenness occurs in the irradiation with ultraviolet rays depending on the thickness of a resin layer, and the bismaleimide resin cannot be uniformly cured. There is also a problem that a filler such as a flame retardant, a curing agent, or an antiwear agent, added to the bismaleimide resin blocks the ultraviolet rays, and hinders curing of the bismaleimide resin.

Therefore, there is a demand for resin-clad copper foil which can be manufactured without irradiation with ultraviolet rays in a case where the bismaleimide resin is used.

### CITATION LIST

### Patent Literature

[PTL 1] JP-A-2003-243836

### SUMMARY OF INVENTION

### Technical Problem

The present invention has been made in view of the above problems, and an object thereof is to provide resin-clad copper foil which can improve transmission characteristics by using a bismaleimide resin having a low dielectric constant and a low dielectric loss tangent, and which can be manufactured without irradiation with ultraviolet rays, and a printed wiring hoard using the same.

### Solution to Problem

In order to solve the above problems, resin-clad copper foil of the present invention includes a resin composition laminated on, copper foil containing a bismaleimide resin represented by general formula (1) below, a curing agent, and a filler, the blending amount of the filler being 10 to 200 parts by mass based on 100 parts by mass of a resin component, the resin composition having a complex viscosity at 80° C. of 1×10³ Pa·s to 5×10 Pa·s.

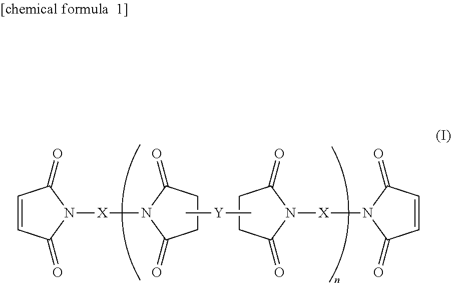

Here, in formula (I), X represents an aliphatic, alicyclic, or aromatic hydrocarbon group having 10 to 30 carbon atoms in the main chain, the group may have a hetero atom, a substituent, or a siloxane skeleton, Y represents an aliphatic, alicyclic, or aromatic hydrocarbon group, the group may have a hetero atom, a substituent, a phenyl ether skeleton, a sulfonyl skeleton, or a siloxane skeleton, and n represents a number in a range of 1 to 20.

The bismaleimide compound represented by the above general formula (I) may be a compound in which X in general formula (I) has an alkyl group having 10 to 30 carbon atoms as the main chain, and two side chains bonded to mutually adjacent carbons in the alkyl group to partially form a cyclic structure.

The filler may be silica and/or fluororesin powder, and the curing agent may be one or two or more selected from a radical initiator, an imidazole-based curing agent, and a cation-based curing agent.

A printed wiring board cm be manufactured using these resin-clad copper foils.

### Advantageous Effects of Invention

According to the present invention, by using a bismaleimide resin having a low dielectric constant and a low dielectric loss tangent, it is possible to provide resin-clad copper foil which can improve the transmission characteristics, reduce the flow of the resin composition at the time of press molding, and be manufactured without irradiation with ultraviolet rays.

### Description of Embodiments

Hereinafter, embodiments of the present invention will be described in detail.

Resin-clad copper foil according to the present embodiment includes a resin composition laminated on a part or the whole of a surface of copper foil, the resin composition including a bismaleimide resin, a curing agent, and a filler, the blending amount of the filler being 10 to 200 parts by mass based on 100 parts by mass of a resin component, the resin composition having a complex viscosity at 80° C. of 1×10³ Pa·s to 5×10⁵ Pa·s.

As the bismaleimide resin, a resin represented by general formula (I) below is used.

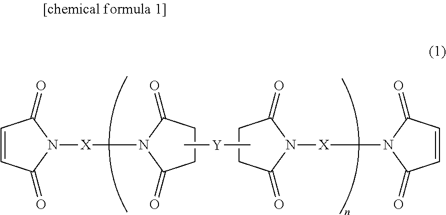

In Formula (I), X represents an aliphatic, alicyclic, or aromatic hydrocarbon group having 10 to 30 carbon atoms in the main chain, and these groups may have a hetero atom, a substituent, or a siloxane skeleton. X is preferably an aliphatic hydrocarbon group, an alicyclic hydrocarbon group, or an aliphatic hydrocarbon group modified with an alicyclic hydrocarbon group. More preferably, the number of carbon atoms in a hydrocarbon group represented by X, including one or more side chain if any, is 10 to 55, and even more preferably 10 to 40. Particularly preferably, X is an alkyl group having 10 to 30 carbon atoms as a main chain, and two side chains bonded to mutually adjacent carbons in the alkyl group to partially form a cyclic structure.

Y represents an aliphatic, alicyclic, or aromatic hydrocarbon group, and these groups may have a hetero atom, a substituent, a phenyl ether skeleton, a sulfonyl skeleton, or a siloxane skeleton. Y is preferably an aromatic hydrocarbon group.

n is the number of repeating units and represents a number in a range of 1 to 20, n is preferably in a range of 1 to 15, and snore preferably in a range of 1 to 10 from the viewpoint of obtaining a flexible resin. When n is 20 or less, resin-clad copper foil having excellent strength can be obtained. Although one type of the bismaleimide compound in which n is 1 to 20 may be used alone, or two or more types thereof may be used in combination, it is more preferable that the bismaleimide compound is a mixture of compounds in which n is 1 to 10.

The method for manufacturing the above bismaleimide compound is not particularly limited, and it can be manufactured, for example, by a known method of subjecting an acid anhydride and a diamine to a condensation reaction, and thereafter dehydrating to effect cyclization (imidization).

Examples of acid anhydrides that can be used for the manufacture include maleic anhydride grafted polybutadiene; maleic anhydride grafted polyethylene; polyethylene-maleic anhydride alternating copolymers; poly-maleic anhydride-1-octadecene alternating copolymer; maleic anhydride grafted polypropylene; poly(styrene-maleic anhydride) copolymer; pyromellitic anhydride; maleic anhydride, succinic anhydride; 1,2,3,4-cyclobutanetetracarboxylic acid dianhydride; 1,4,5,8-naphthalenetetracarboxylic acid dianhydride; 3,4,9,10-perylenetetracarboxylic acid dianhydride; bicyclo (2.2.2) oct-7-ene-2,3,5,6-tetracarboxylic acid dianhydride; diethylenetriamine pentaacetic acid dianhydride; ethylenediamine tetraacetic acid dianhydride; 3,3′-benzophenonetetracarboxylic acid dianhydride; 3,3′,4,4′-biphenyltetracarboxylic acid dianhydride; 4,4′-oxydiphthalic anhydride; 3,3′,4,4′-diphenylsulfone tetracarboxylic acid dianhydride; 2,2′-bis(3,4-dicarboxyphenyl) hexafluoropropane dianhydride; 4,4′-bisphenol A diphthalic anhydride; 5-(2,5-dioxytetrahydro)-3-methyl-3-cyclohexene-1,2-dicarboxylic acid anhydride; ethylene glycol bis(trimellitic anhydride); hydroquinone diphthalic anhydride; allyl nadic anhydride; 2-octen-1-ylsuccinic anhydride: phthalic anhydride; 1,2,3,6-tetrahydrophthalic anhydride; 3,4,5,6-tetrahydrophthalic anhydride; 1,8-naphthalic anhydride; glutaric anhydride; dodecenylsuccinic anhydride; hexadecenylsuccinic anhydride; hexahydrophthalic anhydride; methylhexahydro phthalic anhydride; tetradecenylsuccinic anhydride, and the like.

In addition, examples of diamines include 1,10-diaminodecane; 1,12-diaminadodecane; dimer diamine; 1,2-diamino-2-methylpropane; 1,2-diaminocyclohexane; 1,2-diaminopropane; 1,3-diaminopropane; 1,4-diaminobutane; 1,5-diaminopentane; 1,7-diaminoheptane; 1,8-diaminomentane; 1 ,8-diammooctane; 1,9-diaminononane; 3,3′-diamino-N-methyldipropylamine; diaminomaleonitrile; 1,3-diaminopentane; 9,10-diaminophenanthrene; 4,4′-diaminooctafluorobiphenyl; 3,5-diaminobenzoic acid: 3,7-diamino-2-methoxyfluorene; 4,4′-diaminobenzophenone; 3,4-diaminobenzophenone; 3,4-diaminotoluene; 2,6-diaminoanthraquinone; 2,6-diaminotoluene 2,3-diaminotoluene; 1,8-dianminonaphthalene; 2,4-diaminotoluene; 2,5-diaminotoluene; 1,4-diaminoanthraquinone; 1,5-diaminoanthraquinone; 1,5-diaminonaphthalene; 1,2-diaminoanthraquitione; 2,4-cumene diamine; 1,3-bisaminomethylbenzene; 1,3-bisamino methylcyclohexane; 2-chloro-1,4-diaminobenzene; 1,4-diamino-2,5-dichlorobenzene; 1,4-diamino-2,5-dimethylbezene; 4,4′-diamino-2,2′-bistrifluoromethylbiphenyl; bis(amino-3-chlorophenyl) ethane; bis(4-amino-3,5-dimethylphenyl) methane; bis(4-amino-3,5-diethylphenyl) methane; bis(4-amino-3-ethyldiaminofluorene; diaminobenzoic acid; 2,3-diaminonaphthalene; 2,3-diaminophenol; -5-methylphenyl) methane; bis(4-amino-3-methylphenyl) methane; bis(4-amino-3-ethylphenyl) methane; 4,4′-diaminophenyl sulfone: 3,3′-diaminophenyl sulfone; 2,2-bis(4-(4aminophenoxy)phenyl) sulfone; 2,2-bis(4-(3-aminophenoxy)phenyl) sulfone; 4,4′-oxydianiline, 4,4′-diaminodiphenyl sulfide; 3,4′-oxydianiline; 2,2-bis(4-(4-aminophenoxy) phenyl) propane; 1,3-bis(4-aminophenoxy) benzene; 4,4′-bis(4-aminophenoxy) biphenyl; 4,4′-diamino-3,3′-dihydroxybiphenyl; 4,4′-diamino-3,3′-dimethylbiphenyl; 4,4′-diamino-3,3′-dimethoxybiphenyl; Bisaniline M; Bisaniline P; 9,9-bis(4-aminophenyl) fluorene; o-tolidine sulfone; methylene bis(anthranilic acid); 1,3-bis(4-aminophenoxy)-2,2-dimethylpropane; 1,3-bis(4-aminophenoxy) propane; 1,4-bis(4-aminophenoxy) butane; 1,5-bis(4-aminophenoxy) butane; 2,3,5,6-tetramethyl-1,4 -phenylenediamine; 3,3′,5,5′-tetramethylbenzene; 4,4′-diaminobenzanilide; 2,2-bis(4-aminophenyl) hexafluoropropane; polyoxyalkylene diamines (for example, Huntsman's Seffamine D-230, D400, D-2000, and D-4000); 1,3-cyclohexane bis(methylamine); m-xylylene (hairline; p-xylylene diamine; bis(4-amino-3-methylcyclohexyl) methane; 1,2-bis(2-aminoethoxy) ethane; 3(4),8 (9)-bis(aminomethyl) tricyclo(5.2.1.0^{2,6}) decane, 1,2-bis(aminooctyl)-3-octyl-4-hexyl-cyclohexane, and the like. Among these, from the viewpoint of obtaining resin-clad copper foil exhibiting excellent dielectric properties and strength, it is preferable to be a diamine having 10 to 30 carbon atoms in the main chain of the alkyl chain.

As the above bismaleimide compound, a commercially available compound can be used, and as a preferred example thereof, BMI-3000 (synthesized from dimer diamine, pyromellitic dianhydride and maleic anhydride), BMI-1500, BMI-2550, BMI-1400, BMI-2310, BM-3005 manufactured by DESIGNER MOLECURES Inc., or the like may be suitably used.

Among these, BMI-3000 manufactured by DESIGNER MOLECURES Inc., which is particularly suitable to be used in the present invention is represented by following structural formula. In the formula, n is a number in the range of 1 to 20.

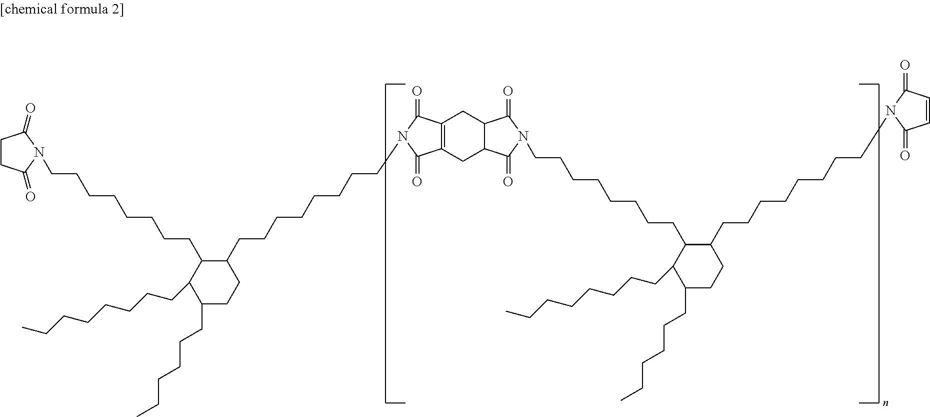

The curing agent is not particularly limited, and one selected from the group consisting of a radical initiator, an imidazole-based curing agent and a cation-based curing agent can be used alone, or two or more selected from the group can be used in blending.

Examples of radical-based curing agents (polymerization initiator) include di-cumyl peroxide, t-butyl cumyl peroxide, t-butyl hydroperoxide, cumene hydroperoxide, azo-based compounds, and the like.

Examples of imidazole-based curing agents include imidazole, 2-undecylimidazole, 2-heptadecylimidazole, 2-ethylimidazole, 2-phenylimidazole, 2-ethyl-4-methylimidazole, 1-cyanoethyl-2-undecylimidazole, 2,4-diamino-6-[2′-methylimidazolyl-(1′)]-ethyl-s-triazine, and the like.

Examples of cation-based curing agents include amine salts of boron trifluoride, onium-based compounds represented by P-methoxybenzene diazonium hexafluorophosphate, diphenyliodonium hexafluorophosphate, triphenylsulfonium, tetra-n-butylphosphonium tetraphenylborate, tetra-n-butylphosphonium-o,o-diethylphosphorodithioate, and the like.

The blending amount of the curing agent is not particularly limited, and the blending amount is preferably 0.5 to 30 parts by mass, more preferably 1 to 20 parts by mass, and even more preferably 1 to 15 parts by mass, based on 100 parts by mass of the resin component. When the blending amount is 0.5 parts by mass or more, curing becomes sufficient to ensure adhesion, and when the blending amount is 30 parts by mass or less, pot life can be ensured within a range not impairing workability.

The filler is not particularly limited, and silica and fluororesin powder are suitably used, and both of these can be used in combination.

Examples of silica include synthetic silica, amorphous silica (wet type or dry type), colloidal silica, hollow silica, porous silica, and the like. From the viewpoint of further lowering a dielectric constant the hollow silica is preferable.

Examples of fluororesin powder include perfluoroalkoxy fluororesin, tetrafluoroethylene—hexafluoropropylene copolymer, ethylene—tetrafluoroethylene copolmyer, and ethylene—chlorotrifluoroethylene copolymer.

The particle diameter of the fluororesin powder is not particularly limited, and the average particle diameter is preferably 0.2 μm to 30 μm.

The blending amount of the filler is preferably 10 to 200 parts by mass, and more preferably 20 to 200 parts by mass based on 100 parts by mass of the resin component.

In a case where the filler is a fluororesin powder, the blending amount is preferably 40 to 200 parts by mass, and more preferably 60 to 180 parts by mass based on 100 parts by mass of the resin component.

The resin composition to be laminated on the resin-clad copper foil of the present invention can be obtained by blending predetermined amounts of the above components and sufficiently mixing the components with a solvent to be used as necessary.

The solvent is not particularly limited, and an organic solvent is preferably used, and specific examples thereof include methyl ethyl ketone, toluene, methanol, tetralin, and the like. Any of these solvents may be used alone, or two or more types thereof may be used in blending.

Although the amount of the solvent to be used is not particularly limited, it is preferably 20 to 200 parts by mass, more preferably 30 to 150 parts by mass, and even more preferably 30 to 100 parts by mass, based on 100 parts by mass of the resin component.

In addition, additives which have been added to the same type of resin composition in the related art may be added to the above resin composition within a range not deviating from the object of the present invention.

The complex viscosity of the above resin composition at 80° C. in the absence of a solvent is preferably 1×10³ Pa·s to 5×10⁵ Pa·s, more preferably 1×10⁴ Pa·s to 5×10⁵ Pa·s, and further preferably 5×10⁴ Pa·s to 5×10⁵ Pa·s.

When the complex viscosity at 80° C. is 1×10³ Pa·s or more, the flow of the resin composition is unlikely to occur at the time of press molding which makes molding easy even if temporary curing is not performed by ultraviolet rays. When the complex viscosity at 80° C. is 5×10⁵ Pa·s or less, the fluidity of the resin composition is appropriate, so that it is possible to fill a step of the patterned copper foil or the like at the time of molding the multilayer board.

In addition, the above resin composition can be blended with an epoxy resin to improve the adhesion within a range not adversely affecting a dielectric constant or a dielectric loss tangent.

The epoxy resin may be used as long as the resin contains an epoxy group in the molecule, and specific examples thereof include a bisphenol A type epoxy resin, a bisphenol F type epoxy resin, a glycidyl amine-based epoxy resin, a glycidyl ether-based epoxy resin, a glycidyl ester-based epoxy resin, and the like.

When the epoxy resin is used, the blending amount of the epoxy resin is not particularly limited, and the blending amount is preferably 1 to 25 parts by mass, more preferably 2 to 20 parts by mass, and further preferably 2 to 15 parts by mass in 100 parts by mass of the resin component.

The above resin composition can be used for the resin-clad copper foil. Here, the resin-dad copper foil refers to a composite material in which the copper foil is coated with a semi-cured resin serving as a base material.

The method for manufacturing the resin-clad copper foil of the present invention is not particularly limited. For example, the above resin composition is applied to a release-treated polyethylene terephthalate (PET) film so as to have a uniform thickness and a film is obtained by removing the solvent. The film is attached to a copper plate, pressed while being heated, and cured by which resin-clad copper foil can be obtained. In this case, the pressing conditions are not particularly limited, and it is preferable to press while heating for 5 to 10 minutes under a condition that a heating temperature is 80CC to 130° C. and a surface pressure is 5 to 20 kg/cm².

The resin-clad copper foil can be used for a printed wiring board such as a copper-clad laminate or a flexible printed wiring board.

The copper-clad laminate is a type of material for printed circuit boards, and refers to a product obtained by laminating copper foil on the above-described composition or a fiber base material such as glass cloth impregnated with the above-described composition.

The method for manufacturing the copper-clad laminate is not particularly limited. For example, according to a method in the related art, a copper-clad laminate can be manufactured by attaching the resin surface of the resin-clad copper foil according to the present invention so as to be in contact with the fiber base material and molding by pressing while heating. Regarding the press conditions at this time, it is preferable that the pressing is performed for 30 to 120 minutes under a condition that a heating temperature is 160° C. to 200° C. and a surface pressure is 15 to 40 kg/cm², and more preferable that the pressing is performed for 30 to 90 minutes under a condition that a heating temperature is 160° C. to 180° C. and a surface pressure is 20 to 30 kg/cm². Resin-clad copper foil may be provided on both sides of the fiber base material.

The flexible printed wiring board refers to a board on which an electric circuit is formed on a base material formed by attaching a film (polyimide or the like) including a flexible insulator to a conductive metal such as copper foil.

The method for manufacturing the flexible printed wiring board is not particularly limited. For example, according to a method in the related art, a flexible printed wiring board can be obtained by forming a circuit on the copper-clad laminate by pattern etching, and laminating the cover lay by thermocompression bonding. At this time, it is preferable to press for 30 to 120 minutes under a condition that a heating temperature is 160° C. to 200° C. and a surface pressure is 15 to 40 kg/cm, and more preferable to press for 30 to 90 minutes under a condition that a heating temperature is 160° C. to 180° C. and a surface pressure is 20 to 30 kg/cm².

### EXAMPLES

Examples of the present invention are described below, but the present invention is not limited by the following examples. In the following, the mixing, proportion, and the like are based on mass unless otherwise specified.

In accordance with the mixture illustrated in Table 1 below, a bismaleimide resin, an epoxy resin, a curing agent, and a filler were mixed to obtain a resin composition laminated on copper foil.

Details of each component in Table 1 are as follows.

Bismaleimide resin: “BMI-3000CG” manufactured by DESIGNER MOLECULES INC., 50% by mass of toluene solution

Epoxy resin: “VG3101L” manufactured by Printech Co., Ltd., 50% by mass of methyl ethyl ketone solution

Radical-based curing agent: cumene hydroperoxide

Imidazole-based curing agent: “2E4M7 (2-ethyl-4-methylimidazole)” manufactured by Shikoku Chemicals Corporation

Cation-based curing agent: tetra-n-butylphosphonium tetraphenylborate

silica: “WG 1000” manufactured by Toyo Kasei Co., Ltd.

Fluororesin powder: “KTL-500F” manufactured by Kitamura Co., Ltd.

The obtained resin composition was applied to a release-treated PET film so as to have a thickness of approximately 100 μm , and a solvent was removed at 50° C. for 30 minutes to manufacture a film.

A complex viscosity, a dielectric constant, a dielectric loss tangent, a shear strength, a flow of the resin composition, and a step filling property of the obtained resin composition and film, were measured and evaluated.

Complex viscosity: Six of the obtained films were superimposed and used as measurement samples. The complex viscosity was measured using the following device under the following measurement conditions.

Device name: Modular Compact Rheometer MCR302 manufactured by Anton Paar Co., Ltd.

Swing angle: 0.1%

Frequency: 1 Hz

Measuring range: 25° C. to 200° C.

Heating rate: 5° C./min

Dielectric constant or Dielectric loss tangent: The obtained resin composition was poured into a mold having a depth of 0.7 mm, a length of 120 mm, and a width of 70 mm, flattening the surface with a metal spatula, and leaving the resin composition at ordinary temperature for 24 hours to dry the solvent. Thereafter, the resin composition was placed in a mold made of a fluororesin having a thickness of 0.5 mm, a length of 110 mm, and a width of 70 mm, and the upper and lower sides of the mold were interposed between fluororesin sheets and pressed at 180° C. for 60 minutes at 1 MPa to obtain a molded article. As a press machine, a high-temperature vacuum press machine (KVHC-II type) manufactured by Kitagawa Seiki Co., Ltd. was used.

The obtained molded article was cut in the longitudinal direction with a width of approximately 2 mm to prepare a sample. Dielectric constant and dielectric loss tangent of three samples were measured by a cavity resonator perturbation method respectively, and average values of three samples were obtained. As a network analyzer, E8361A manufactured by Agilent Technologies, Inc. was used, and as a cavity resonator, CP531 (10 GHz) manufactured by Kanto Electronic. Application Development Co., Ltd. was used.

When the value of the dielectric constant is 2.5 or less, the molded article can be suitably used for a printed wiring board having excellent transmission characteristics. When the value of the dielectric loss tangent is 0.005 or less, the molded article can be suitably used for a printed wiring board having excellent transmission characteristics.

Shear strength: The obtained resin composition was applied to a copper plate and dried, and the shear strength before and after the solder dipping test was measured in accordance with HS K 6850. In the solder dipping test, the test piece was floated in a solder bath at 260° C. for 30 seconds.

When the value of shear strength is 3 MPa or more, the molded article can be suitably used for a printed wiring board, and the value is more preferably 4 MPa or more.

Flow of resin composition: The obtained film was cut into a rectangle (20 cm×15 cm), superimposed on a shiny surface of the same size copper foil (thickness of 18 μm), and pressed for 5 minutes under a condition of 130° C. and 1 MPa in a high temperature vacuum press machine (KVHC-II type manufactured by Kitagawa Seiki Co., Ltd.) to obtain resin-clad copper foil. Subsequently, the resin-clad copper foil was observed with an optical microscope (80 times), and the degree of flow of the resin composition was evaluated. When the flow of the resin composition was 0.3 mm or less, it was defined as “good”, and when the flow rate of the resin composition is larger than 0.3 mm, it was defined as “poor”.

Step filling property: The obtained resin-clad copper foil was pressed for 60 minutes at 170° C. and a surface pressure of 2.5 MPa on a flexible printed board having copper foil thickness of 35 μm and a pattern of line and space (line/space) of 100 μm/100 μm. The cross section of the sample was observed with an optical microscope (80 times), and it was evaluated whether the step was filled with the composition. When the step was filled with the composition, it was defined as “good”, and when the gap was confirmed in the step, it was defined as “poor”.

TABLE 1

| | | | | | | | | Comparative | Comparative |
|---|---|---|---|---|---|---|---|---|---|
| | | Example 1 | Example 2 | Example 3 | Example 4 | Example 5 | Example 6 | Example 1 | Example 2 |
| Bismaleimide resin | | 100 | 95 | 100 | 100 | 95 | 100 | 100 | 100 |
| Epoxy resin | | — | 5 | — | — | 5 | — | — | — |
| Radical-based curing agent | | 2 | 2 | 2 | 2 | 2 | 2 | 2 | 2 |
| Imidazole-based curing agent | | — | — | — | — | 2 | — | — | — |
| Cation-based curing agent | | — | 2 | — | — | — | — | — | — |
| Silica | | — | — | — | — | — | 20 | — | — |
| Fluororesin powder | | 60 | 60 | 20 | 200 | 60 | 60 | 5 | 250 |
| Complex viscosity at 80° C. (Pa · s) | | 1.31E+04 | 1.71E+05 | 1.14E+03 | 8.20E+04 | 1.53E+04 | 3.30E+04 | 5.14E+02 | 8.00E+05 |
| Dielectric constant (10 GHz) | | 2.39 | 2.48 | 2.32 | 2.1 | 2.5 | 2.45 | 2.4 | 2 |
| Dielectric loss tangent (10 GHz) | | 0.0037 | 0.0044 | 0.0033 | 0.0027 | 0.005 | 0.0038 | 0.0035 | 0.0023 |
| Shear strength | Initial | 4.91 | 5.85 | 5.12 | 4.58 | 8.34 | 5.15 | 5.22 | 2.7 |
| (MPa) | After solder | 4.37 | 5.9 | 5.03 | 4.25 | 8.22 | 4.83 | 5.05 | 2 |
| | dipping | | | | | | | | |

| | | | | | | | | |
|---|---|---|---|---|---|---|---|---|
| Flow of resin composition | good | good | good | good | good | good | poor | good |
| Step filling property | good | good | good | good | good | good | good | poor |

The results are indicated in Table 1. In the examples using the resin composition which includes a bismaleimide resin, a curing agent, and a filler, in which the blending amount of the filler is 10 to 200 parts by mass: based on 100 parts by mass of a resin component, and which has a complex viscosity at 80° C. of 1×10³ & Pa·s to 5×10⁵ Pa·s, since the resin composition has appropriate flowability, it is possible to cure the resin composition without causing a flow of the resin composition at the time of pressing, and the resin composition was able to fill the step.

On the other hand, in Comparative Example 1 using the resin composition in which the content of the filler was small, and the complex viscosity at 80° C. was lower than 1×10³ Pa·s, the complex viscosity of the resin composition was too low, so that a flow of the resin composition occurred at the time of press molding. In Comparative Example 2, the complex viscosity of the resin composition was too high, so that it was impossible to fill the step. In addition, the shear strength was less than 3, and sufficient strength could not be obtained.

1. Resin-clad copper foil in which a resin composition is laminated on a part or the whole of a surface of copper foil,
wherein the resin composition includes a bismaleimide resin represented by general formula (I) below, a curing agent, and a filler,
the blending amount of the filler is 10 to 200 parts by mass based on 100 parts by mass of a resin component, and
the resin composition has a complex viscosity at 80° C. of 1×10³ Pa·s to 5×10⁵ Pa·s. 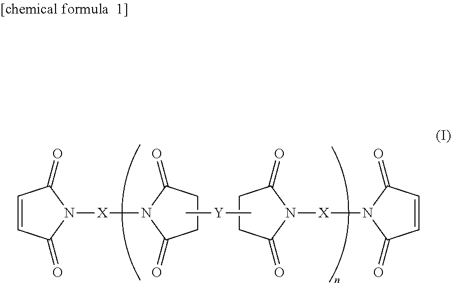
In formula (I), X represents an aliphatic, alicyclic, or aromatic hydrocarbon group having 10 to 30 carbon atoms in the main chain, these groups optionally have a hetero atom, a substituent, or a siloxane skeleton, Y represents an aliphatic, alicyclic, or aromatic hydrocarbon group, these groups optionally have a hetero atom, a substituent, a phenyl ether skeleton, a sulfonyl skeleton, or a siloxane skeleton, and n represents a number in a range of 1 to 20.

2. The resin-clad copper foil according to claim 1,
wherein the bismaleimide resin represented by the above general formula (I) is a compound in which X in general formula (I) has an alkyl group having 10 to 30 carbon atoms as the main chain, and two side chains bonded to mutually adjacent carbons in the alkyl group partially form a cyclic structure.

3. The resin-clad copper foil according to claim 1,
wherein the filler is silica and/or fluororesin powder.

4. The resin-clad copper foil according to claim 1.
wherein the curing agent is one or two or more selected from a radical initiator, an imidazole-based curing agent and a cation-based curing agent.

5. A printed wiring board which is obtained by using the resin-clad copper foil according to claim 1.
